(19) United States
(12) Patent Application Publication
(10) Pub. No.: US 2014/0342641 A1
(43) Pub. Date: Nov. 20, 2014

(54) POLISHING PAD

(71) Applicant: TOYO TIRE & RUBBER CO., LTD., Osaka-shi, Osaka (JP)

(72) Inventor: Shinji Shimizu, Osaka-shi (JP)

(21) Appl. No.: 14/365,023

(22) PCT Filed: Dec. 14, 2012
(86) PCT No.: PCT/JP2012/082552

§ 371 Date: Jun. 12, 2014

(30) Foreign Application Priority Data
Dec. 16, 2011 (JP) 2011-275991
Nov. 5, 2012 (JP) 2012-243560
Dec. 10, 2012 (JP) 2012-269215

(51) Int. Cl. B24B 37/24; H01L 21/304; B24D 11/00

(52) U.S. Cl. CPC B24B 37/24; B24D 11/001; H01L 21/304
USPC 451/41; 451/526; 51/296

(57) ABSTRACT

An object of the present invention is to provide a polishing pad which hardly generates scratches on the surface of an object to be polished, and has improved dressability. Another object of the present invention is to provide a method for manufacturing a semiconductor device using the polishing pad. A polishing pad of the present invention includes a polishing layer made of a fine cell-containing polyurethane resin foam, wherein the polyurethane resin foam contains a polyurethane resin having an Asker D hardness of 20 to 60 degrees and an abrasion parameter, which is expressed by the following equation, of 1 to 3.

Abrasion parameter={1/(Tensile breaking strength [MPa]×Tensile breaking elongation [%]/100)}×100

### TECHNICAL FIELD

The invention relates to a polishing pad capable of performing planarization of materials requiring a high surface planarity such as optical materials including a lens and a reflecting mirror, a silicon wafer, a glass substrate or an aluminum substrates for a hard disc and a product of general metal polishing with stability and a high polishing efficiency. A polishing pad of the invention is preferably employed, especially, in a planarization step of a silicon wafer or a device on which an oxide layer or a metal layer has been formed prior to further stacking an oxide layer or a metal layer thereon.

### BACKGROUND ART

Typical materials requiring surface flatness at high level include a single-crystal silicon disk called a silicon wafer for producing semiconductor integrated circuits (IC, LSI). The surface of the silicon wafer should be flattened highly accurately in a process of producing IC. LSI etc., in order to provide reliable semiconductor connections for various coatings used in manufacturing the circuits. In the step of polishing finish, a polishing pad is generally stuck on a rotatable supporting disk called a platen, while a workpiece such as a semiconductor wafer is stuck on a polishing head. By movement of the two, a relative speed is generated between the platen and the polishing head while polishing slurry having abrasive grains is continuously supplied to the polishing pad, to effect polishing processing.

As polishing characteristics of a polishing pad, it is requested that a polished object is excellent in planarity and within wafer non-uniformity and a polishing rate is large. A planarity and within wafer non-uniformity of a polished object can be improved to some extent with a polishing layer higher in elastic modulus. A polishing rate can be bettered by increasing a holding quantity of a slurry on a foam with cells therein.

Polishing pads including a polyurethane resin foam are proposed as polishing pads that meet the above properties (see Patent Documents 1 and 2). Such a polyurethane resin foam is produced by a reaction of an isocyanate-terminated prepolymer with a chain extender (curing agent).

In addition, Patent Document 3 discloses a polishing pad comprising a polyurethane polymeric material that is formed from a curative agent and an isocyanate-terminated reaction product obtained by a prepolymer reaction between a polyol and a polyfunctional aromatic isocyanate, the isocyanate-terminated reaction product having 4.5 to 8.7% by weight unreacted NCO.

Generally, when planarization of a large number of semiconductor wafers is performed using a polishing pad, a fine uneven portion of the surface of the polishing pad is worn to deteriorate the performance of supplying the polishing agent (slurry) to the surface to be processed of the semiconductor wafer, decrease the speed of planarizing the surface to be processed of the wafer, or deteriorate the planarization characteristics. Therefore, after having performed the planarization of a predetermined number of semiconductor wafers, it is necessary to renew/roughen (dress) the surface of the polishing pad by using a dresser. When dressing is carried out for a predetermined period of time, uncountable fine uneven portions are produced on the surface of the polishing pad, so that the surface of the polishing pad becomes fluffy.

However, the conventional polishing pad has a problem that the dressing speed during dressing is low and such dressing takes too much time.

In order to solve the above problem, Patent Document 4 proposes a technique of using a polymerized diisocyanate and an aromatic diisocyanate as an isocyanate component that is a starting material for polyurethane resin foams.

However, there is a tendency such that when a polymerized diisocyanate is used, the hardness of the polyurethane resin foam increases and when a polishing pad formed of the polyurethane resin foam is used, scratches are likely to occur on the surface of an object to be polished.

### PRIOR ART DOCUMENT

### Patent Documents

Patent Document 1: JP-A-2000-17252

Patent Document 2: Japanese patent No. 3359629

Patent Document 3: US-A-2005/0171225

Patent Document 4: JP-A-2006-297582

### SUMMARY OF THE INVENTION

### Problems to be Solved by the Invention

An object of the present invention is to provide a polishing pad which hardly generates scratches on the surface of an object to be polished, and has improved dressability. Another object of the present invention is to provide a polishing pad having high polishing rate as compared with a conventional polishing pad in addition to the properties described above, and to provide a method for manufacturing the polishing pad. A further object of the present invention is to provide a polishing pad having excellent planarization properties in addition to the aforementioned properties as compared with a conventional polishing pad. A still further object of the present invention is to provide a method for manufacturing a semiconductor device using the polishing pad.

### Means for Solving the Problems

As a result of investigations to solve the problems, the inventors have found that the objects can be achieved with the polishing pad described below, and have completed the invention.

Specifically, the invention is related to a polishing pad comprising a polishing layer made of a fine cell-containing polyurethane resin foam, wherein the polyurethane resin foam contains a polyurethane resin having an Asker D hardness of 20 to 60 degrees and an abrasion parameter, which is expressed by the following equation, of 1 to 3.

Abrasion parameter={1/(Tensile breaking strength [MPa]×Tensile breaking elongation [%]/100)}×100

Since a polyurethane resin (non-foamed product) serving as a material for forming the polishing layer of the present invention has low hardness and is flexible as compared with a polyurethane resin used as a material of forming a conventional polishing layer, scratches are unlikely to occur on the surface of an object to be polished. A flexible polyurethane resin generally tends to become small in abrasion parameters because of its excellent plasticity. However, in spite of the flexibility, the polyurethane resin serving as a material for forming the polishing layer of the present invention has a large abrasion parameter and excellent dressability. Therefore, by using the polyurethane resin specified in the present invention as the material for forming the polishing layer, it is possible not only to suppress scratches on the surface of the object to be polished, but also to shorten the dressing time, thereby improving a production efficiency of the object to be polished such as a semiconductor wafer.

When the polyurethane resin has an Asker D hardness of less than 20 degrees, the planarization properties of the polishing pad deteriorate, whereas when the polyurethane resin has an Asker D hardness exceeding 60 degrees, scratches become easy to occur on the surface of the object to be polished.

When the polyurethane resin has an abrasion parameter of less than 1, the polishing rate is lowered due to poor dressability or the production efficiency of a semiconductor wafer or the like is reduced because the dressing takes too much time. On the other hand, when the polyurethane resin has an abrasion parameter of more than 3, the polishing layer surface becomes too rough in the case where the polishing layer surface is dressed with a dresser. As a result, scratches are easily generated on the surface of the object to be polished, or the polishing rate decreases, or the pad life is shortened.

The polyurethane resin foam preferably has a cell number of 200/mm² or more and an average cell diameter of 50 μm or less. A polyurethane resin foam produced by a conventional mechanical foaming method has a cell number of about 150 to 180/mm² and an average cell diameter of about 55 to 70 μm. The polyurethane resin foam having a cell number of 200/mm² or more and an average cell diameter of 50 μm or less is very excellent in slurry holding property because the cell number is large and the average cell diameter is small as compared with a conventional polyurethane resin foam. Therefore, the polishing rate of a polishing pad having a polishing layer made of the polyurethane resin foam is very high as compared with a conventional polishing pad. If the cell number is less than 200/mm² or the average cell diameter exceeds 50 μm, an effect of improving the polishing rate becomes insufficient.

The polyurethane resin preferably contains, as raw material components, a chain extender and an isocyanate-terminated prepolymer obtained by reacting a prepolymer raw material composition containing a polymerized diisocyanate and an aromatic diisocyanate as isocyanate components, a high molecular weight polyol, and an active hydrogen group-containing low molecular weight compound. The polyurethane resin obtained by a prepolymer method is preferable because of its excellent polishing properties.

A content of the polymerized diisocyanate is 15 to 60% by weight based on the total isocyanate components, and an NCO wt % of the isocyanate-terminated prepolymer is preferably 5 to 8 wt %. By adjusting the content of the polymerized diisocyanate and the NCO wt % of the isocyanate-terminated prepolymer to the above range, it is easy to produce a polyurethane resin having an Asker D hardness of 20 to 60 degrees and an abrasion parameter of 1 to 3.

In the present invention, the polymerized diisocyanate is preferably a polymerized aliphatic diisocyanate, and the aromatic diisocyanate is preferably toluene diisocyanate. The polymerized aliphatic diisocyanate is particularly preferably a polymerized hexamethylene diisocyanate. By using these diisocyanates, it is possible to produce a polyurethane resin foam with good handling properties.

Further, the polyurethane resin foam produced by using the polyurethane resin preferably has an Asker D hardness of 10 to 45 degrees. If the Asker D hardness is less than 10 degrees, an object to be polished has a tendency to reduce its planarity. On the other hand, if the Asker D hardness is more than 45 degrees, an object to be polished has good planarity, but has a tendency to reduce its in-plane uniformity. Further, scratches tend to easily occur on the surface of the object to be polished.

Further, the polyurethane resin foam produced by using the polyurethane resin preferably has a specific gravity of 0.5 to 1.0. If the specific gravity is less than 0.5, there are the tendencies that the hardness of the polishing layer as a whole becomes too low, so that planarization properties deteriorate, or the lifetime of the polishing pad may be shortened because the surface abrasion of the polishing layer is larger than necessary, or the stability of the polishing rate decreases as a result of immediate removal of fluffs on the surface of the polishing layer after dressing, at the time of polishing a wafer. On the other hand, if the specific gravity is greater than 1.0, it becomes hard to sufficiently improve the dressability of the polishing layer.

Further, a polyurethane resin foam obtained by foaming a polyurethane resin with hollow microspheres is excellent in compressive elasticity as compared with a conventional polyurethane resin foam obtained by a chemical foaming method or a mechanical foaming method. Therefore, a polishing pad having a polishing layer made of the polyurethane resin foam is excellent in planarization properties as compared with a conventional polishing pad.

Further, the invention is related to a method for manufacturing the polishing pad, comprising a step of producing the polyurethane resin foam by stirring a first component containing an isocyanate-terminated prepolymer, a silicone surfactant, and a tertiary amine catalyst with a non-reactive gas so that the non-reactive gas is dispersed as fine cells to prepare a cell dispersion liquid, then mixing the cell dispersion liquid with a second component containing a chain extender, followed by curing the mixture,

wherein the isocyanate-terminated prepolymer is a prepolymer obtained by reacting a prepolymer raw material composition containing a polymerized diisocyanate and an aromatic diisocyanate as isocyanate components, a high molecular weight polyol, and an active hydrogen group-containing low molecular weight compound, and

a content of the tertiary amine catalyst is 0.1 to 3 parts by weight based on 100 parts by weight of the isocyanate-terminated prepolymer.

According to the manufacturing method of the present invention, it is possible to easily produce a polyurethane resin foam containing a polyurethane resin having an Asker D hardness of 20 to 60 degrees and an abrasion parameter of 1 to 3, the polyurethane resin foam further having a cell number of 200/mm² or more and an average cell diameter of 50 μm or less. When the content of the tertiary amine catalyst is less than 0.1 parts by weight based on 100 parts by weight of the isocyanate-terminated prepolymer, it becomes difficult to produce a polyurethane resin foam having a cell number of 200/mm² or more and an average cell diameter of 50 μm or less, whereas when the content of the tertiary amine catalyst is more than 3 parts by weight, the curing reaction excessively accelerates so that the handling properties tend to worsen.

Further, the invention is related to a method for manufacturing a semiconductor device, comprising a step of polishing a surface of a semiconductor wafer by using the polishing pad.

### Effect of the Invention

In the present invention, a polyurethane resin having an Asker D hardness of 20 to 60 degrees and an abrasion parameter of 1 to 3 is used as the polyurethane resin serving as a material for forming a polishing layer, and the polyurethane resin is characterized by its large abrasion parameter and excellent dressability in spite of low hardness and flexibility. Therefore, by using the polyurethane resin as a material for forming a polishing layer (material for forming polyurethane resin foam), it is possible not only to suppress scratches on the surface of the object to be polished, but also to shorten the dressing time, thereby improving a production efficiency of the object to be polished such as a semiconductor wafer.

Since the polyurethane resin foam of the present invention has a cell number of 200/mm² or more and an average cell diameter of 50 μm or less, the resin foam is very excellent in slurry holding property. Therefore, a polishing pad having a polishing layer made of the polyurethane resin foam has very high polishing rate as compared with a conventional polishing pad.

Further, the polyurethane resin foam of the present invention obtained by being foamed with the use of hollow microspheres is excellent in compressive elasticity. Therefore, a polishing pad having a polishing layer made of the polyurethane resin foam is excellent in planarization properties as compared with a conventional polishing pad.

### BRIEF DESCRIPTION OF THE DRAWINGS

FIG. 1 is a schematic diagram showing a typical polishing apparatus for use in CMP polishing.

### MODE FOR CARRYING OUT THE INVENTION

The polishing pad of the invention includes a polishing layer made of a fine cell-containing polyurethane resin foam. The polishing pad of the invention may be only the polishing layer or a laminated body of the polishing layer and any other layer (such as a cushion layer).

The polyurethane resin serving as a material for forming the polishing layer (polyurethane resin foam) is excellent in abrasion resistance, and it is possible to easily obtain a polymer having desired physical properties by variously changing the raw material composition, and therefore, the polyurethane resin is a particularly preferred material as a material for forming the polishing layer.

The polyurethane resin is made of an isocyanate component, an active hydrogen group-containing compound (high molecular weight polyol, active hydrogen group-containing low molecular weight compound), a chain extender and the like.

As the isocyanate component, a compound known in the field of polyurethane can be used without particular limitation. The isocyanate component includes, for example, aromatic diisocyanates such as 2,4-toluene diisocyanate, 2,6-toluene diisocyanate, 2,2′-diphenyl methane diisocyanate, 2,4′-diphenyl methane diisocyanate, 4,4′-diphenyl methane diisocyanate, polymeric MDI, carbodiimide-modified MDI (for example, Millionate MTL made by Nippon Polyurethane Industry Co., Ltd.), 1,5-naphthalene diisocyanate, p-phenylene diisocyanate, m-phenylene diisocyanate, p-xylylene diisocyanate and m-xylylene diisocyanate, aliphatic diisocyanates such as ethylene diisocyanate, 2,2,4-trimethyl hexamethylene diisocyanate and 1,6-hexamethylene diisocyanate, and cycloaliphatic diisocyanates such as 1,4-cyclohexane diisocyanate, 4,4′-dicyclohexyl methane diisocyanate, isophorone diisocyanate and norbornane diisocyanate. These may be used alone or as a mixture of two or more thereof.

A polymerized diisocyanate may be used together with the diisocyanate described above. The polymerized diisocyanate is an isocyanate-modified product that is polymerized by the addition of three or more diisocyanates, or a mixture thereof. Examples of the isocyanate-modified product include 1) trimethylolpropane adduct type, 2) biuret type, and 3) isocyanurate type, among which the isocyanurate type is particularly preferred.

In the present invention, it is preferred to use, as the isocyanate components, the polymerized diisocyanate in combination with the aromatic diisocyanate. As a diisocyanate to form the polymerized diisocyanate, an aliphatic diisocyanate is preferably used, and 1,6-hexamethylene diisocyanate is particularly preferably used. Further, urethane-modified, allophanate-modified, and Biuret-modified products may be used as the polymerized diisocyanate. The aromatic diisocyanate is preferably toluene diisocyanate.

The polymerized diisocyanate is used in an amount of preferably 15 to 60% by weight, more preferably 19 to 55% by weight, based on the total isocyanate components.

As the high molecular weight polyol, examples thereof include polyether polyols represented by polytetramethylene ether glycol; polyester polyols represented by polybutylene adipate; polyester polycarbonate polyols exemplified by reaction products of polyester glycol such as polycaprolactone polyol or polycaprolactone and alkylene carbonate; polyester polycarbonate polyols obtained by reacting ethylene carbonate with polyvalent alcohol and the reacting the resultant reaction mixture with an organic dicarboxylic acid; and polycarbonate polyols obtained by ester exchange reaction between polyhydroxyl compound and aryl carbonate. These may be used singly or in combination of two or more kinds.

No limitation is imposed on a number-average molecular weight of a high molecular weight polyol but it is preferably 500 to 5000 from the viewpoint of an elastic characteristic of an obtained polyurethane resin. If a number-average molecular weight thereof is less than 500, a polyurethane resin obtained by using the polyol does not have a sufficient elastic characteristic and easy to be brittle, and a polishing pad made from the polyurethane resin is excessively hard, which sometimes causes scratches to be generated on a surface of an object to be polished. On the other hand, if a number-average molecular weight thereof exceeds 5000, a polishing pad made from a polyurethane resin obtained from such a polyol is unpreferably soft to thereby disable a sufficiently satisfiable planarity.

In addition to the high molecular weight polyol, an active hydrogen group-containing low molecular weight compound may be used. The active hydrogen group-containing low molecular weight compound refers to a compound having a molecular weight of less than 500, examples thereof include a low molecular weight polyol such as ethylene glycol, 1,2-propylene glycol, 1,3-propylene glycol, 1,2-butanediol, 1,3-butanediol, 1,4-butanediol, 2,3-butanediol, 1,6-hexanediol, neopentyl glycol, 1,4-cyclohexanedimethanol, 3-methyl-1,5-pentanediol, diethylene glycol, triethyleneglycol, 1,4-bis(2-hydroxyethoxy)benzene, trimethylolpropane, glycerin, 1,2,6-hexanetriol, pentaerythritol, tetramethylolcyclohexane, methyl glucoside, sorbitol, mannitol, dulcitol, sucrose, 2,2,6,6-tetrakis(hydroxymethyl)cyclohexanol, diethanolamine, N-methyldiethanolamine, triethanolamine and the like; a low molecular weight polyamine such as ethylenediamine, tolylenediamine, diphenylmethanediamine, diethylenetriamine and the like; an alcoholamines such as monoethanolamine, 2-(2-aminoethylamino)ethanol, monopropanolamine and the like. These active hydrogen group-containing low molecular weight compound may be used alone or as a mixture of two or more thereof.

The ratio of the high molecular weight polyol and the active hydrogen group-containing low molecular weight compound is determined by the properties required for the polishing layer to be made therefrom.

In a case where a polyurethane resin is produced by means of a prepolymer method, a chain extender is used in curing of a prepolymer. A chain extender is an organic compound having at least two active hydrogen groups and examples of the active hydrogen group include: a hydroxyl group, a primary or secondary amino group, a thiol group (SH) and the like. Concrete examples of the chain extender include: polyamines such as 4,4′-methylenebis(o-chloroaniline) (MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 4,4′-diamino-3,3′,5,5′-tetraethyldiphenylmethane, 4,4′-diamino-3,3′-diisopropyl-5.5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5.5′-dimethyldiphenylmethane, N,N′-di-sec-butyl-4,4′-diaminophenylmethane, 3,3′-diethyl-4,4′-diaminodiphenylmethane, m-xylylenediamine, N,N′-di-sec-butyl-p-phenylenediamine, m-phenylenediamine and p-xylylenediamine; the low molecular weight polyol described above; and the low molecular weight polyamine described above. The chain extenders described above may be used either alone or in mixture of two kinds or more.

In the present invention, a polyurethane resin foam is produced by using a polyurethane resin having an Asker D hardness of 20 to 60 degrees and an abrasion parameter of 1 to 3. The Asker D hardness of the polyurethane resin is preferably 25 to 60 degrees, more preferably 30 to 60 degrees. The abrasion parameter of the polyurethane resin is preferably 1 to 2, more preferably 1 to 1.5.

A polyurethane resin foam can be produced by applying a melting method, a solution method or a known polymerization technique by using the raw material of the polyurethane resin, among which preferable is a melting method, consideration being given to a cost, a working environment and the like.

Manufacture of a polyurethane resin foam is enabled by means of either a prepolymer method or a one shot method, of which preferable is a prepolymer method in which an isocyanate-terminated prepolymer is synthesized from an isocyanate component and an active hydrogen group-containing compound in advance, with which a chain extender is reacted since physical properties of an obtained polyurethane resin is excellent.

In the synthesis of the isocyanate-terminated prepolymer, the number of isocyanate groups in the isocyanate component is preferably from 1.5 to 3.0, more preferably 1.8 to 2.5, based on the number of active hydrogen groups (hydroxyl group, amino group) in the active hydrogen group-containing compound.

In the synthesis of the isocyanate-terminated prepolymer, it is preferable to adjust the NCO wt % to 5 to 8 wt %, more preferably 5.8 to 8 wt %.

The ratio of the isocyanate-terminated prepolymer and the chain extender can be variously changed depending on each molecular weight and the desired physical properties of the polishing pad. In order to obtain a polishing pad having desired polishing properties, the number of isocyanate groups in the prepolymer is preferably 0.80 to 1.20, more preferably 0.99 to 1.15, based on the number of active hydrogen groups (hydroxyl group, amino group) of the chain extender. If the number of isocyanate groups is outside the above range, there is a tendency that curing failure occurs, so that the specific gravity and hardness to be required cannot be obtained, leading to a deterioration in polishing properties.

The method for manufacturing the polyurethane resin foam may be a method of adding hollow microspheres, a mechanical foaming method (including a mechanical frothing), a chemical foaming method, or the like. Any combination of these methods may be used.

In the case of the mechanical foaming method, it is preferable to use a silicone surfactant comprising a copolymer of polyalkylsiloxane and polyether. Compounds suitable as the silicone surfactant include SH-192 and L-5340 (manufactured by Dow Corning Toray Silicone Co., Ltd.), B8443 and B8465 (manufactured by Goldschmidt Chemical Corporation), and the like. The silicone surfactant is preferably added at a concentration of 0.05 to 10% by weight, more preferably 0.1 to 5% by weight, to the polyurethane-forming raw material composition.

Incidentally, if necessary, stabilizers (e.g. antioxidants), lubricants, pigments, fillers, antistatic agents, and other additives may be added.

Description will be given hereinafter of an example of a method for manufacturing a closed cell type thermosetting polyurethane resin foam constituting a polishing pad (polishing layer) by the mechanical foaming method. A method of manufacturing such a polyurethane resin foam has the following steps:

### 1) Foaming Step of Preparing Cell Dispersion Liquid

The step includes adding a silicone surfactant to the first component containing the isocyanate-terminated prepolymer so that the polyurethane resin foam will contain 0.05 to 10% by weight of the silicone surfactant and stirring the mixture in the presence of a non-reactive gas to form a cell dispersion liquid in which the non-reactive gas is dispersed in the form of fine cells. In a case where the prepolymer is solid at an ordinary temperature, the prepolymer is preheated to a proper temperature and used in a molten state.

### 2) Curing Agent (Chain Extender) Mixing Step

The second component containing a chain extender is added into the cell dispersion liquid, which is agitated to thereby obtain a foaming reaction liquid.

### 3) Casting Step

The forming reaction liquid is cast into a mold.

### 4) Curing Step

The foaming reaction liquid having been cast into the mold is heated and reaction-cured.

In the production of the polyurethane resin foam, a known catalyst promoting polyurethane reaction, such as tertiary amine catalysts, may be used. The type and amount of the catalyst added are determined in consideration of flow time in casting in a predetermined mold after the mixing step.

In the method for manufacturing the polyurethane resin foam of the present invention, it is preferable to add a tertiary amine catalyst to the first component. This makes it possible to reduce the fluidity of the foaming reaction liquid in a short time (in other words, quick curing is possible). As a result, it is possible to suppress the integration between air bubbles in the foaming reaction liquid during casting step and curing step, and to reduce the cell diameter by increasing the cell number. Even in the case of using an isocyanate-terminated prepolymer having small NCO wt %, it is possible to produce a polyurethane resin foam having large cell number and small cell diameter.

The amount of the tertiary amine catalyst added is preferably 0.1 to 3 parts by weight, more preferably 0.2 to 1.5 parts by weight, based on 100 parts by weight of the isocyanate-terminated prepolymer.

The non-reactive gas used for forming fine cells is preferably not combustible, and is specifically nitrogen, oxygen, a carbon dioxide gas, a rare gas such as helium and argon, and a mixed gas thereof, and the air dried to remove water is most preferable in respect of cost.

As a stirrer for dispersing the silicone-based surfactant-containing first component to form fine cells with the non-reactive gas, known stirrers can be used without particular limitation, and examples thereof include a homogenizer, a dissolver, a twin-screw planetary mixer etc. The shape of a stirring blade of the stirrer is not particularly limited either, but a whipper-type stirring blade is preferably used to form fine cells.

In a preferable mode, different stirrers are used in stirring for forming a cell dispersion liquid in the stirring step and in stirring for mixing an added chain extender in the mixing step, respectively. In particular, stirring in the mixing step may not be stirring for forming cells, and a stirrer not generating large cells is preferably used. Such a stirrer is preferably a planetary mixer. The same stirrer may be used in the stirring step and the mixing step, and stirring conditions such as revolution rate of the stirring blade are preferably regulated as necessary.

In the method of producing the polyurethane resin foam, heating and post-curing of the foam obtained after casting and reacting the forming reaction liquid in a mold until the dispersion lost fluidity are effective in improving the physical properties of the foam, and are extremely preferable. The forming reaction liquid may be cast in a mold and immediately post-cured in a heating oven, and even under such conditions, heat is not immediately conducted to the reactive components, and thus the diameters of cells are not increased. The curing reaction is conducted preferably at normal pressures to stabilize the shape of cells.

Production of the polyurethane resin foam may be in a batch system where each component is weighed out, introduced into a vessel and mixed or in a continuous production system where each component and a non-reactive gas are continuously supplied to, and stirred in, a stirring apparatus and the resulting forming reaction liquid is transferred to produce molded articles.

A manufacturing method of a polishing pad may be performed in ways: in one of which a prepolymer which is a raw material from which a polyurethane resin foam is made is put into a reaction vessel, thereafter a chain extender is mixed into the prepolymer, the mixture is agitated, thereafter the mixture is cast into a mold with a predetermined size to thereby prepare a block and the block is sliced with a slicer like a planer or a band saw; and in another of which in the step of casting into the mold, a thin sheet may be directly produced.

The average cell diameter of the polyurethane resin foam is preferably 100 μm or less, more preferably 50 μm or less, particularly preferably 30 to 50 μm. If the average cell diameter is out of this range, the planarity (flatness) of the object to be polished after polishing tends to be reduced.

The cell number of the polyurethane resin foam is preferably 200/mm² or more, more preferably 250/mm² or more.

On the other hand, when the hollow microspheres are used, they may be added to the first component containing an isocyanate-terminated prepolymer or to the second component containing a chain extender, but it is preferred to add the hollow microspheres to the first component in order to be uniformly dispersed in the polyurethane resin foam.

The hollow microspheres are those in which the inside of the microsphere is hollow and the outer shell thereof is made of resin. In the present invention, known hollow microspheres may be used without particular limitation, and examples thereof include EXPANCEL DE (manufactured by Japan Fillite Co., Ltd.), MICROPEARL (manufactured by Matsumoto Yushi Kogyo Co., Ltd.), ARBOCEL (manufactured by Rettenmaier & Sohne), Matsumoto Microsphere F (manufactured by Matsumoto Yushi-Seiyaku Co., Ltd.), and the like.

The amount of the hollow microspheres added is not particularly limited, but the hollow microspheres are preferably added in an amount of 1.5 to 6.0% by weight, more preferably 2.5 to 4.5% by weight, to the polyurethane resin foam.

Incidentally, if necessary, stabilizers (e.g. antioxidants), lubricants, pigments, fillers, antistatic agents, and other additives may be added.

Description will be given hereinafter of an example of a method for manufacturing a thermosetting polyurethane resin foam constituting a polishing pad (polishing layer) by using hollow microspheres. A method for manufacturing the polyurethane resin foam has the following steps.

### 1) Mixing Step of Hollow Microspheres

Hollow microspheres are added to a first component containing an isocyanate-terminated prepolymer to a concentration of 1.5 to 6.0% by weight of the polyurethane resin foam, followed by uniform dispersing to obtain a dispersion liquid. When the prepolymer is in a solid form at normal temperature, the prepolymer is used after being melted by pre-heating to an appropriate temperature.

### 2) Mixing Step of Curing Agent (Chain Extender)

A second component containing a chain extender is added to the dispersion liquid, followed by mixing to obtain a reaction liquid.

### 3) Casting Step

The reaction liquid is poured into a mold.

### 4) Curing Step

The reaction liquid poured into the mold is reaction-cured by heating.

In the method of producing the polyurethane resin foam, heating and post-curing of the foam obtained after casting and reacting the reaction liquid in a mold until the dispersion lost fluidity are effective in improving the physical properties of the foam, and are extremely preferable.

A known catalyst promoting polyurethane reaction, such as tertiary amine catalysts, may be used. The type and amount of the catalyst added are determined in consideration of flow time in casting in a predetermined mold after the mixing step.

Production of the polyurethane resin foam may be in a batch system where each component is weighed out, introduced into a vessel and mixed or in a continuous production system where each component is continuously supplied to, and stirred in, a stirring apparatus and the resulting reaction liquid is transferred to produce molded articles.

A manufacturing method of a polishing pad may be performed in ways: in one of which a prepolymer and hollow microspheres which are a raw material from which a polyurethane resin foam is made is put into a reaction vessel, thereafter a chain extender is mixed into the reaction vessel, the mixture is agitated, thereafter the mixture is cast into a mold with a predetermined size to thereby prepare a block and the block is sliced with a slicer like a planer or a band saw; and in another of which in the step of casting into the mold, a thin sheet may be directly produced. Besides, a still another way may be adopted in which a resin of raw material is melted, the melt is extruded through a T die to thereby mold a polyurethane resin foam directly in the shape of a sheet.

The hollow microspheres in the polyurethane resin foam have an average cell diameter of preferably 20 to 60 μm, more preferably 30 to 50 μm. When the diameter falls outside this range, the planarity after polishing of the object to be polished tends to be reduced.

The polyurethane resin foam has a specific gravity of preferably 0.5 to 1.0, more preferably 0.6 to 0.9, particularly preferably 0.7 to 0.8.

The polyurethane resin foam has a hardness of preferably 10 to 45 degrees, more preferably 15 to 35 degrees, particularly preferably 20 to 35 degrees as measured with an Asker D hardness meter.

A polishing pad (polishing layer) of the invention is preferably provided with a surface structure for holding and renewing a slurry. The polishing layer formed of the foam has many openings at its polishing surface to have a function of holding and renewing a slurry. A depression and protrusion structure is preferably provided to the polishing surface in order to efficiently achieve further holding and renewal of a slurry or in order to prevent an object to be polished from being broken by adsorption between the polishing pad and the object to be polished. Though in a case where the polishing layer is formed with an unfoamed body, which lacks in work to hold and renew the slurry, a depression and protrusion structure are preferably provided on the surface of the polishing side thereof in order to achieve more of holdability and renewal of the slurry or in order to prevent induction of dechuck error or breakage of an object to be polished. The shape of the depression and protrusion structure is not particularly limited insofar as slurry can be retained and renewed, and examples include latticed grooves, concentric circle-shaped grooves, through-holes, non-through-holes, polygonal prism, cylinder, spiral grooves, eccentric grooves, radial grooves, and a combination of these grooves. The groove pitch, groove width, groove thickness etc. are not particularly limited either, and are suitably determined to form grooves. These depression and protrusion structure are generally those having regularity, but the groove pitch, groove width, groove depth etc. can also be changed at each certain region to make retention and renewal of slurry desirable.

The method of forming the depression and protrusion structure is not particularly limited, and for example, formation by mechanical cutting with a jig such as a bite of predetermined size, formation by casting and curing resin in a mold having a specific surface shape, formation by pressing resin with a pressing plate having a specific surface shape, formation by photolithography, formation by a printing means, and formation by a laser light using a CO₂ gas laser or the like.

The thickness of the polishing layer is not particularly limited, and is usually about 0.8 to 4 mm, preferably 1.0 to 2.5 mm.

A polishing pad of the invention may also be a laminate of a polishing layer and a cushion sheet adhered to each other.

The cushion sheet (a cushion layer) compensates for characteristics of the polishing layer. The cushion sheet is required for satisfying both planarity and uniformity which are in a tradeoff relationship in CMP. Planarity refers to flatness of a pattern region upon polishing an object to be polished having fine unevenness generated upon pattern formation, and uniformity refers to the uniformity of the whole of an object to be polished. Planarity is improved by the characteristics of the polishing layer, while uniformity is improved by the characteristics of the cushion sheet. The cushion sheet used in the polishing pad of the present invention is preferably softer than the polishing layer.

The material forming the cushion sheet is not particularly limited, and examples of such material include a nonwoven fabric such as a polyester nonwoven fabric, a nylon nonwoven fabric or an acrylic nonwoven fabric, a nonwoven fabric impregnated with resin such as a polyester nonwoven fabric impregnated with polyurethane, polymer resin foam such as polyurethane foam and polyethylene foam, rubber resin such as butadiene rubber and isoprene rubber, and photosensitive resin.

Means for adhering the polishing layer to the cushion sheet include: for example, a method in which a double sided tape is sandwiched between the polishing layer and the cushion sheet, followed by pressing.

The double sided tape is of a common construction in which adhesive layers are provided on both surfaces of a substrate such as a nonwoven fabric or a film. It is preferable to use a film as a substrate with consideration given to prevention of permeation of a slurry into a cushion sheet. A composition of an adhesive layer is, for example, of a rubber-based adhesive, an acrylic-based adhesive or the like. An acrylic-based adhesive is preferable because of less of a content of metal ions, to which consideration is given. Since a polishing layer and a cushion sheet is sometimes different in composition from each other, different compositions are adopted in respective adhesive layers of double sided tape to thereby also enable adhesive forces of the respective adhesive layers to be adjusted to proper values.

A polishing pad of the invention may be provided with a double sided tape on the surface of the pad adhered to a platen. As the double sided tape, a tape of a common construction can be used in which adhesive layers are, as described above, provided on both surfaces of a substrate. As the substrate, for example, a nonwoven fabric or a film is used. Preferably used is a film as a substrate since separation from the platen is necessary after the use of a polishing pad. As a composition of an adhesive layer, for example, a rubber-based adhesive or an acrylic-based adhesive is exemplified. Preferable is an acrylic-based adhesive because of less of metal ions in content to which consideration is given.

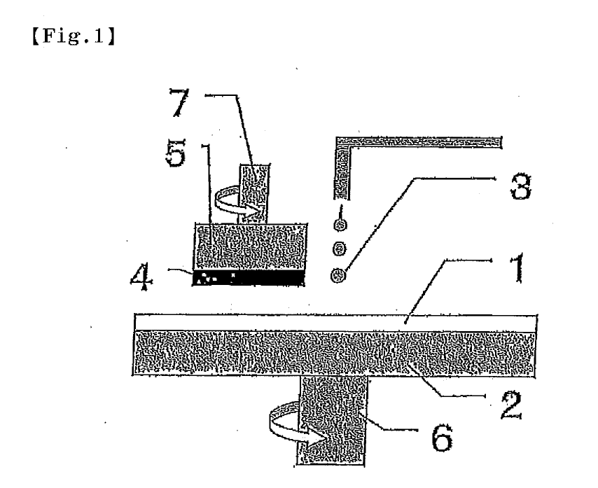

A semiconductor device is fabricated after operation in a step of polishing a surface of a semiconductor wafer with a polishing pad. The term, a semiconductor wafer, generally means a silicon wafer on which a wiring metal and an oxide layer are stacked. No specific limitation is imposed on a polishing method of a semiconductor wafer or a polishing apparatus, and polishing is performed with a polishing apparatus equipped, as shown in FIG. 1, with a polishing platen 2 supporting a polishing pad (a polishing layer) 1, a polishing head 5 holding a semiconductor wafer 4, a backing material for applying a uniform pressure against the wafer and a supply mechanism of a polishing agent 3. The polishing pad 1 is mounted on the polishing platen 2 by adhering the pad to the platen with a double sided tape. The polishing platen 2 and the polishing head 5 are disposed so that the polishing pad 1 and the semiconductor wafer 4 supported or held by them oppositely face each other and provided with respective rotary shafts 6 and 7. A pressure mechanism for pressing the semiconductor wafer 4 to the polishing pad 1 is installed on the polishing head 5 side. During polishing, the semiconductor wafer 4 is polished by being pressed against the polishing pad 1 while the polishing platen 2 and the polishing head 5 are rotated and a slurry is fed. No specific limitation is placed on a flow rate of the slurry, a polishing load, a polishing platen rotation number and a wafer rotation number, which are properly adjusted.

Protrusions on the surface of the semiconductor wafer 4 are thereby removed and polished flatly. Thereafter, a semiconductor device is produced therefrom through dicing, bonding, packaging etc. The semiconductor device is used in an arithmetic processor, a memory etc.

### EXAMPLES

Description will be given of the invention with examples, while the invention is not limited to description in the examples.

### [Measurement and Evaluation]

### (Measurement of Cell Number and Average Cell Diameter)

Using a utility knife, the produced polyurethane resin foam was cut so that a cross-section becomes as flat as possible, and the cross-section was photographed using a scanning electron microscope (S-3500N, manufactured by Hitachi Science Systems, Ltd.) at a magnification of 100 times. Subsequently, image analysis software (WIN-ROOF, manufactured by Mitani Corporation) was used to measure the cell number in an arbitrary area and the equivalent circle diameter of all cells. From the measured values, the cell number per 1 mm² and the average cell diameter per 600 cells were calculated.

### (Measurement of Hardness)

Measurement is conducted according to JIS K6253-1997. A manufactured non-foamed polyurethane resin sheet and a manufactured polyurethane resin foam sheet cut out in a size of 2 cm×2 cm (thickness: arbitrary) was used as a sample for measurement of hardness and left for 16 hours in an environment of a temperature of 23±2° C. and a humidity of 50%±5%. At the time of measurement, samples were stuck on one another to a thickness of 6 mm or more. A hardness meter (Asker D hardness meter, manufactured by Kobunshi Keiki Co., Ltd.) was used to measure hardness.

### (Measurement of Tensile Breaking Strength and Tensile Breaking Elongation)

In accordance with JIS K7312-1996, the produced non-foamed polyurethane resin sheet was punched into a shape of dumbbell No. 3 to obtain a sample. The sample was aged for 24 hours under the conditions of 22° C. and 66% RH, and then subjected to a tensile test. A tensile breaking strength (MPa) and a tensile breaking elongation (%) were measured. Autograph AG-X (manufactured by Shimadzu Corporation) was used as a tensile tester, and a video extension meter was used. The tensile speed was 50 mm/minute.

### (Calculation of Abrasion Parameters)

The abrasion parameters were calculated by substituting in the following equation the values of the tensile breaking strength and tensile breaking elongation obtained by the above measurement.

Abrasion parameter={1/(Tensile breaking strength [MPa]×Tensile breaking elongation [%]/100)}×100

### (Measurement of Specific Gravity)

Determined according to JIS Z8807-1976. A manufactured polyurethane resin foam sheet cuts out in the form of a strip of 4 cm×8.5 cm (thickness: arbitrary) was used as a sample for measurement of specific gravity and left for 16 hours in an environment of a temperature of 23±2° C. and a humidity of 50%±5%. Measurement was conducted by using a specific gravity hydrometer (manufactured by Sartorius Co., Ltd).

### (Evaluation of Polishing Properties)

Using SPP600S (manufactured by Okamoto Machine Tool Works, Ltd.) as a polishing apparatus, the polishing properties of the prepared polishing pad were evaluated. A thermal oxide film of 1 μm was made on a silicon wafer of 8 inch, the film was polished for 60 seconds, and the polishing rate was calculated from the polishing amount of the film. For measuring the thickness of the oxide film, a light interference type film thickness measuring instrument (instrument name: Nanospec, manufactured by Nanometrics Corporation) was used. As the polishing conditions, silica slurry (SS12, manufactured by Cabot Corporation) was added at a flow rate of 150 ml/minute during polishing. The polishing loading was 350 g/cm², the number of revolutions of polishing platen was 35 rpm, and the number of revolutions of wafer was 30 rpm.

Planarization properties were evaluated by the following method. A thermal oxide film was deposited 0.5 μm on an 8 inch silicon wafer, patterning of L/S (line and space)=25 μm/5 μm and L/S=5 μm/25 μm was performed, and an oxide film (TEOS) was further deposited 1 μm to produce a wafer with a pattern at an initial step of 0.5 μm. This wafer was polished under the aforementioned polishing conditions, and the cutting amount of a bottom part of a 25 μm space was measured at a global step of 2000 angstroms or less, to thereby evaluate the planarization properties. It can be said that as the value of the cutting amount is smaller, the planarization properties are excellent.

### (Evaluation of Scratches)

Four 8-inch dummy wafers were polished under the above conditions, and then a wafer with a 10,000-angstroms thick thermal oxide film deposited thereon was polished for 1 minute. Subsequently, a defect evaluation apparatus manufactured by KLA-Tencor Corporation (Surfscan SP1) was used to determine how many scratches of 0.19 μm or more were there on the polished wafer.

### (Measurement of Dressing Speed)

A surface of the produced polishing pad was uniformly dressed with a diamond dresser (M Type #100 in the shape of a circle with a diameter of 20 cm, manufactured by Asahi Diamond Industrial Co., Ltd.) while being rotated. The dressing conditions at this time were a dresser load of 50 g/cm² or 450 g/cm², a polishing platen rotation number of 30 rpm, a dresser rotation number of 15 rpm and a dressing time of 60 minutes. The dressing speed was calculated from thicknesses of the polishing pad as measured before and after the dressing.

### Example 1

### Production of Non-Foamed Polyurethane Resin Sheet

In a vessel were placed 18.2 parts by weight of toluene diisocyanate (TDI-80, a mixture of 2,4-diisocyanate/2,6-diisocyanate=80/20, manufactured by Mitsui Chemicals, Inc.), 22.5 parts by weight of polymerized 1,6-hexamethylene diisocyanate (Sumijule N-3300 (isocyanurate type) manufactured by Sumika Bayer Urethane Co., Ltd.), 57.1 parts by weight of polytetramethylene ether glycol (PTMG 1000, hydroxyl value: 112.2 KOH mg/g, manufactured by Mitsubishi Chemical Corporation), and 2.2 parts by weight of 1,4-butanediol (1,4-BG, manufactured by Nacalai Tesque, Inc.), and the mixture was allowed to react at 70° C. for 4 hours to obtain an isocyanate-terminated prepolymer A. Note that the content of the polymerized 1,6-hexamethylene diisocyanate was 55% by weight based on the total isocyanate components.

In a planetary mixing and defoaming apparatus were placed 100 parts by weight of the prepolymer A and 19.9 parts by weight of 4,4′-methylenebis(o-chloroaniline), which had been melted at 120° C., and defoamed to prepare a polyurethane raw material composition. The composition was poured into an open mold (casting vessel) (200 mm in length, 200 mm in width, and 2 mm in depth) and subjected to postcuring at 100° C. for 16 hours to produce a non-foamed polyurethane resin sheet.

### (Production of Polishing Pad)

To a polymerization vessel were added 100 parts by weight of the prepolymer A and 3 parts by weight of a silicone surfactant (B8465, manufactured by Goldschmidt Chemical Corporation) and then mixed. The mixture was adjusted to 80° C. in the vessel and was defoamed under reduced pressure. Subsequently, the reaction system was vigorously stirred for about 4 minutes with a stirring blade at a rotational speed of 900 rpm so that air bubbles were incorporated into the reaction system. Thereto was added 19.9 parts by weight of 4,4′-methylenebis(o-chloroaniline), which had been previously melted at 120° C. The liquid mixture was stirred for about 1 minute and then poured into a loaf-shaped open mold (casting vessel). At the point when the liquid mixture lost its fluidity, it was placed in an oven, and subjected to postcuring at 100° C. for 16 hours, so that a polyurethane resin foam block was obtained. While heated at about 80° C., the polyurethane resin foam block was sliced using a slicer (VGW-125, manufactured by Amitec Corporation), so that a polyurethane resin foam sheet was obtained. Subsequently, the surface of the sheet was buffed with a buffing machine (manufactured by Amitec Corporation) until the sheet had a thickness of 1.27 mm. As a result, the sheet had adjusted thickness accuracy. The buffed sheet was punched to form a disc with a diameter of 61 cm, and processing of concentric circular grooves each with a width of 0.25 mm, a pitch of 1.50 mm, and a depth of 0.40 mm was performed on the surface of the sheet using a grooving machine (manufactured by Techno Corporation) so that a polishing layer was obtained. A double-faced adhesive tape (Double Tack Tape, manufactured by Sekisui Chemical Co., Ltd.) was bonded to the surface of the polishing layer opposite to the grooved surface using a laminator. The surface of a corona-treated cushion sheet (Toraypef (0.8 μm-thick polyethylene foam), manufactured by Toray Industries, Inc.) was buffed. The buffed cushion layer was bonded to the double-faced adhesive tape using a laminator. Another double-faced adhesive tape was also bonded to the other side of the cushion layer using a laminator, thereby to produce a polishing pad.

### Examples 2 to 7 and Comparative Examples 1 to 5

Non-foamed polyurethane resin sheets and polishing pads were produced in the same manner as in Example 1, except that the formulations described in Tables 1 and 2 were used. The compounds shown in Tables 1 and 2 are as follows.

LF600D: Prepolymer synthesized from toluene diisocyanate and polytetramethylene ether glycol (NCO wt %=7.25, manufactured by Chemtura Corporation)

LF950A: Prepolymer synthesized from toluene diisocyanate and polytetramethylene ether glycol (NCO wt %=6.05, manufactured by Chemtura Corporation)

L167: Prepolymer synthesized from toluene diisocyanate and polytetramethylene ether glycol (NCO wt %=6.30, manufactured by Chemtura Corporation)

TABLE 1

| Production of non-foamed polyurethane | | | | | | | | |
|---|---|---|---|---|---|---|---|---|
| resin sheet | | Example 1 | Example 2 | Example 3 | Example 4 | Example 5 | Example 6 | Example 7 |
| Synthesis of | PTMG1000 (Parts by weight) | 57.1 | 60.3 | 56.5 | 52.9 | 62.7 | 64.3 | 70.1 |
| prepolymer | 1,4-BG (Parts by weight) | 2.2 | 2.3 | 3.4 | 3.2 | 2.4 | 1.5 | 0 |
| | TDI-80 (Parts by weight) | 18.2 | 24.5 | 26.6 | 19.6 | 28.1 | 22.7 | 19.8 |
| | Sumijule N-3300 (parts by | 22.5 | 12.5 | 13.6 | 24.3 | 6.8 | 11.6 | 10.1 |
| | weight) | | | | | | | |
| | Content of polymerized | 55 | 34 | 34 | 55 | 19 | 34 | 34 |
| | diisocyanate based on | | | | | | | |
| | total isocyanate | | | | | | | |
| | components (% by weight) | | | | | | | |
| | Index [NCO]/[OH] | 2.00 | 2.00 | 2.00 | 2.00 | 2.00 | 2.00 | 2.00 |
| | NCO wt % | 6.85 | 7.28 | 7.90 | 7.40 | 7.53 | 6.75 | 5.89 |
| Kind of prepolymer | | A | B | C | D | E | F | G |
| Prepolymer (parts by weight) | | 100 | 100 | 100 | 100 | 100 | 100 | 100 |
| MOCA (parts by weight) | | 19.9 | 21.1 | 22.9 | 21.4 | 21.8 | 19.1 | 17.1 |
| Index [NCO]/[NH₂] | | 1.1 | 1.1 | 1.1 | 1.1 | 1.1 | 1.1 | 1.1 |
| Physical | D hardness (degree) | 46 | 48 | 60 | 58 | 56 | 44 | 30 |
| properties | Tensile breaking strength | 23.3 | 37.2 | 41.7 | 31.2 | 46.8 | 32.1 | 30.1 |
| | (MPa) | | | | | | | |
| | Tensile breaking | 147 | 206.6 | 167 | 125 | 208.7 | 217.6 | 250 |
| | elongation (%) | | | | | | | |
| | Abrasion parameter | 2.92 | 1.30 | 1.44 | 2.56 | 1.02 | 1.43 | 1.33 |

| Production of non-foamed polyurethane | | Comparative | Comparative | Comparative | Comparative | Comparative |
|---|---|---|---|---|---|---|
| resin sheet | | Example 1 | Example 2 | Example 3 | Example 4 | Example 5 |
| Synthesis of | PTMG1000 (Parts by weight) | 52.5 | 58.5 | — | — | — |
| prepolymer | 1,4-BG (Parts by weight) | 4.4 | 3.5 | — | — | — |
| | TDI-80 (Parts by weight) | 28.5 | 30.6 | — | — | — |
| | Sumijule N-3300 (parts by | 14.6 | 7.4 | — | — | — |
| | weight) | | | | | |
| | Content of polymerized | 34 | 20 | — | — | — |
| | diisocyanate based on | | | | | |
| | total isocyanate | | | | | |
| | components (% by weight) | | | | | |
| | Index [NCO]/[OH] | 2.00 | 2.00 | — | — | — |
| | NCO wt % | 8.49 | 8.19 | — | — | — |
| Kind of prepolymer | | H | I | LF600D | LF950A | L167 |
| Prepolymer (parts by weight) | | 100 | 100 | 100 | 100 | 100 |
| MOCA (parts by weight) | | 24.6 | 23.7 | 20.6 | 17.4 | 18.3 |
| Index [NCO]/[NH₂] | | 1.1 | 1.1 | 1.1 | 1.1 | 1.1 |
| Physical | D hardness (degree) | 70 | 63 | 60 | 50 | 48 |
| properties | Tensile breaking strength | 41.6 | 52.2 | 46.2 | 37.9 | 34.5 |
| | (MPa) | | | | | |
| | Tensile breaking | 147 | 224.4 | 290 | 350 | 400 |
| | elongation (%) | | | | | |
| | Abrasion parameter | 1.64 | 0.85 | 0.75 | 0.75 | 0.72 |

TABLE 2

| Production of polishing pad | | Example 1 | Example 2 | Example 3 | Example 4 | Example 5 | Example 6 | Example 7 |
|---|---|---|---|---|---|---|---|---|
| Kind of prepolymer | | A | B | C | D | E | F | G |
| Prepolymer (parts by weight) | | 100 | 100 | 100 | 100 | 100 | 100 | 100 |
| MOCA (parts by weight) | | 19.9 | 21.1 | 22.9 | 21.4 | 21.8 | 19.1 | 17.1 |
| B8465 (parts by weight) | | 3 | 3 | 3 | 3 | 3 | 3 | 3 |
| Physical | D hardness (degree) | 26 | 26 | 27 | 32 | 30 | 25 | 20 |
| properties | Specific gravity | 0.735 | 0.746 | 0.721 | 0.722 | 0.735 | 0.735 | 0.745 |
| | Polishing rate | 1704 | 1684 | 1659 | 1711 | 1654 | 1653 | 1687 |
| | (angstrom/minute) | | | | | | | |
| | Scratch (number/wafer) | 35 | 45 | 57 | 48 | 42 | 41 | 45 |
| | Dressing speed | 1.2 | 0.9 | 1.1 | 0.9 | 0.6 | 0.7 | 0.7 |
| | (μm/minute) | | | | | | | |
| | Dressing load (50 g/cm²) | | | | | | | |
| | Dressing speed | 25.2 | 14.2 | 18.3 | 19.6 | 10.3 | 12.0 | 13.4 |
| | (μm/minute) | | | | | | | |
| | Dressing load (450 g/cm²) | | | | | | | |

| | | Comparative | Comparative | Comparative | Comparative | Comparative |
|---|---|---|---|---|---|---|
| Production of polishing pad | | Example 1 | Example 2 | Example 3 | Example 4 | Example 5 |
| Kind of prepolymer | | H | I | LF600D | LF950A | L167 |
| Prepolymer (parts by weight) | | 100 | 100 | 100 | 100 | 100 |
| MOCA (parts by weight) | | 24.6 | 23.7 | 20.6 | 17.4 | 18.3 |
| B8465 (parts by weight) | | 3 | 3 | 3 | 3 | 3 |
| Physical | D hardness (degree) | 50 | 41 | 28 | 26 | 26 |
| properties | Specific gravity | 0.750 | 0.743 | 0.747 | 0.738 | 0.745 |
| | Polishing rate | 1657 | 1439 | 1475 | 1357 | 1339 |
| | (angstrom/minute) | | | | | |
| | Scratch (number/wafer) | 256 | 100 | 45 | 35 | 45 |
| | Dressing speed | 1.1 | 0.4 | 0.3 | 0.3 | 0.3 |
| | (μm/minute) | | | | | |
| | Dressing load (50 g/cm²) | | | | | |
| | Dressing speed | 18.5 | 5.6 | 4.3 | 3.3 | 2.6 |
| | (μm/minute) | | | | | |
| | Dressing load (450 g/cm²) | | | | | |

### Example 8

### Production of Polishing Pad

To a polymerization vessel were added 100 parts by weight of the prepolymer F, 3 parts by weight of a silicone surfactant (B8465, manufactured by Goldschmidt Chemical Corporation), and 0.75 parts by weight of a tertiary amine catalyst (KAO: NO25, manufactured by Kao Corporation) and then mixed. The mixture was adjusted to 80° C. in the vessel and defoamed under reduced pressure. Subsequently, the reaction system was vigorously stirred for about 4 minutes with a stirring blade at a rotational speed of 900 rpm so that air bubbles were incorporated into the reaction system. Thereto was added 19.1 parts by weight of 4,4′-methylenebis(o-chloroaniline), which had been previously melted at 120° C. The liquid mixture was stirred for about 1 minute and then poured into a loaf-shaped open mold (casting vessel). At the point when the liquid mixture lost its fluidity, it was placed in an oven, and subjected to postcuring at 100° C. for 16 hours, so that a polyurethane resin foam block was obtained.

While heated at about 80° C., the polyurethane resin foam block was sliced using a slicer (VGW-125, manufactured by Amitec Corporation), so that a polyurethane resin foam sheet was obtained. Subsequently, the surface of the sheet was buffed with a buffing machine (manufactured by Amitec Corporation) until the sheet had a thickness of 1.27 mm. As a result, the sheet had adjusted thickness accuracy. The buffed sheet was punched to form a disc with a diameter of 61 cm, and processing of XY-shaped grooves each with a width of 2.0 mm, a pitch of 15 mm, and a depth of 0.60 mm was performed on the surface of the sheet using a grooving machine (manufactured by Techno Corporation) so that a polishing layer was obtained. A double-faced adhesive tape (Double Tack Tape, manufactured by Sekisui Chemical Co., Ltd.) was bonded to the surface of the polishing layer opposite to the grooved surface using a laminator. The surface of a corona-treated cushion sheet (Toraypef (0.8 μm-thick polyethylene foam), manufactured by Toray Industries, Inc.) was buffed. The buffed cushion layer was bonded to the double-faced adhesive tape using a laminator. Another double-faced adhesive tape was also bonded to the other side of the cushion layer using a laminator, thereby to produce a polishing pad.

### Examples 9 to 10

Polishing pads were produced in the same manner as in Example 8, except that the formulations described in Table 3 were used. The compound shown in Table 3 is as follows.

KAO: NO1; N,N,N′,N′-teramethylhexane-1,6-diamine, manufactured by Kao Corporation

TABLE 3

| | | | | Example |
|---|---|---|---|---|
| Production of polishing pad | | Example 8 | Example 9 | 10 |
| Kind of prepolymer | | F | F | F |
| Prepolymer (parts by weight) | | 100 | 100 | 100 |
| MOCA (parts by weight) | | 19.1 | 19.1 | 19.1 |
| B8465 (parts by weight) | | 3 | 3 | 3 |
| KAO: NO25 (parts by weight) | | 0.75 | 1.25 | — |
| KAO: NO1 (parts by weight) | | — | — | 0.25 |
| Physical | Cell number (cells/mm²) | 280 | 255 | 295 |
| properties | Average cell diameter | 45 | 47 | 45 |
| | (μm) | | | |
| | D hardness (degree) | 25 | 25 | 25 |
| | Specific gravity | 0.745 | 0.746 | 0.757 |
| | Polishing rate | 1905 | 1874 | 1978 |
| | (angstrom/minute) | | | |
| | Scratch (number/wafer) | 25 | 20 | 18 |
| | Dressing speed | 0.9 | 0.9 | 1.1 |
| | (μm/minute) | | | |
| | Dressing load (50 g/cm²) | | | |
| | Dressing speed | 15.0 | 16.5 | 17.9 |
| | (μm/minute) | | | |
| | Dressing load | | | |
| | (450 g/cm²) | | | |

### Example 11

### Production of Polishing Pad

To a polymerization vessel were added 100 parts by weight of the prepolymer F, which had been adjusted to 70° C. and defoamed under reduced pressure, and 4 parts by weight of hollow microspheres (Matsumoto Microsphere F-65DE, manufactured by Matsumoto Yushi-Seiyaku Co., Ltd.) and then mixed with Mazerustar KK-2000 (manufactured by Kurabo Industries Ltd.) for 3 minutes. The resulting mixture was defoamed at 70° C. for 1 hour under reduced pressure to obtain a dispersion. Thereto was added 19.1 parts by weight of 4,4′-methylenebis(o-chloroaniline) (NCO Index: 1.1), which had been previously melted at 120° C., and the mixture was stirred with a hybrid mixer for 1 minute to prepare a reaction solution. The reaction solution was poured into a loaf-shaped open mold (casting vessel). At the point when the reaction solution lost its fluidity, it was placed in an oven, and subjected to postcuring at 100° C. for 16 hours, so that a polyurethane resin foam block was obtained.

While heated at about 80° C., the polyurethane resin foam block was sliced using a slicer (VGW-125, manufactured by Amitec Corporation), so that a polyurethane resin foam sheet was obtained. Subsequently, the surface of the sheet was buffed with a buffing machine (manufactured by Amitec Corporation) until the sheet had a thickness of 1.27 mm. As a result, the sheet had adjusted thickness accuracy. The buffed sheet was punched to form a disc with a diameter of 61 cm, and processing of concentric circular grooves each with a width of 0.25 mm, a pitch of 1.50 mm, and a depth of 0.40 mm was performed on the surface of the sheet using a grooving machine (manufactured by Techno Corporation) so that a polishing layer was obtained. A double-faced adhesive tape (Double Tack Tape, manufactured by Sekisui Chemical Co., Ltd.) was bonded to the surface of the polishing layer opposite to the grooved surface using a laminator. The surface of a corona-treated cushion sheet (Toraypef (0.8 μm-thick polyethylene foam), manufactured by Toray Industries, Inc.) was buffed. The buffed cushion layer was bonded to the double-faced adhesive tape using a laminator. Another double-faced adhesive tape was also bonded to the other side of the cushion layer using a laminator, thereby to produce a polishing pad.

### Examples 12 to 13 and Comparative Examples 6 to 7

Polishing pads were produced in the same manner as in Example 11, except that the formulations described in Table 4 were used.

TABLE 4

| | | Example | Example | Example | Comparative | Comparative |
|---|---|---|---|---|---|---|
| Production of polishing pad | | 11 | 12 | 13 | Example 6 | Example 7 |
| Kind of prepolymer | | F | C | D | H | LF600D |
| Prepolymer (parts by weight) | | 100 | 100 | 100 | 100 | 100 |
| MOCA (parts by weight) | | 19.1 | 22.9 | 21.4 | 24.6 | 20.6 |
| Index [NCO]/[NH₂] | | 1.1 | 1.1 | 1.1 | 1.1 | 1.1 |
| Hollow microspheres (parts by weight) | | 4 | 4 | 4 | 4 | 4 |
| Physical | D hardness (degree) | 27 | 28 | 34 | 52 | 30 |
| properties | Specific gravity | 0.765 | 0.740 | 0.751 | 0.765 | 0.750 |
| | Polishing rate | 1753 | 1785 | 1865 | 1708 | 1547 |
| | (angstrom/minute) | | | | | |
| | Scratch (number/wafer) | 52 | 43 | 47 | 254 | 47 |
| | Cutting amount (angstrom) | 1840 | 1750 | 1650 | 1540 | 3250 |
| | Dressing speed | 0.9 | 1.3 | 1.1 | 1.3 | 0.4 |
| | (μm/minute) | | | | | |
| | Dressing load (50 g/cm²) | | | | | |
| | Dressing speed | 12.8 | 17.5 | 18.7 | 17.5 | 5.2 |
| | (μm/minute) | | | | | |
| | Dressing load (450 g/cm²) | | | | | |

### INDUSTRIAL APPLICABILITY

A polishing pad of the invention is capable of performing planarization materials requiring a high surface planarity such as optical materials including a lens and a reflective mirror, a silicon wafer, an aluminum substrate and a product of general metal polishing with stability and a high polishing efficiency. A polishing pad of the invention is preferably employed, especially, in a planarization step of a silicon wafer or a device on which an oxide layer or a metal layer has been formed prior to further stacking an oxide layer or a metal layer thereon. Further, the polishing pad of the present invention is used preferably as a polishing pad for final polishing.

### DESCRIPTION OF REFERENCE SIGNS

In the drawings, reference numeral 1 represents a polishing pad (polishing layer), 2 a polishing platen, 3 a polishing agent (slurry), 4 an object to be polished (semiconductor wafer), 5 a support (polishing head), 6 and 7 each a rotating shaft.

1. A polishing pad comprising a polishing layer made of a fine cell-containing polyurethane resin foam, wherein the polyurethane resin foam contains a polyurethane resin having an Asker D hardness of 20 to 60 degrees and an abrasion parameter, which is expressed by the following equation, of 1 to 3.
Abrasion parameter={1/(Tensile breaking strength [MPa]×Tensile breaking elongation [%]/100)}×100

2. The polishing pad according to claim 1, wherein the polyurethane resin foam has a cell number of 200/mm² or more and an average cell diameter of 50 μm or less.

3. The polishing pad according to claim 1, wherein the polyurethane resin contains, as raw material components, a chain extender and an isocyanate-terminated prepolymer obtained by reacting a prepolymer raw material composition containing a polymerized diisocyanate and an aromatic diisocyanate as isocyanate components, a high molecular weight polyol, and an active hydrogen group-containing low molecular weight compound.

4. The polishing pad according to claim 3, wherein a content of the polymerized diisocyanate is 15 to 60% by weight based on the total isocyanate components, and an NCO wt % of the isocyanate-terminated prepolymer is 5 to 8 wt %.

5. The polishing pad according to claim 3, wherein the polymerized diisocyanate is a polymerized aliphatic diisocyanate, and the aromatic diisocyanate is toluene diisocyanate.

6. The polishing pad according to claim 5, wherein the polymerized aliphatic diisocyanate is a polymerized hexamethylene diisocyanate.

7. The polishing pad according to claim 1, wherein the polyurethane resin foam has an Asker D hardness of 10 to 45 degrees.

8. The polishing pad according to claim 1, wherein the polyurethane resin foam has a specific gravity of 0.5 to 1.0.

9. The polishing pad according to claim 1, wherein the fine cell is made of hollow microspheres.

10. A method for manufacturing the polishing pad according to claim 1, comprising a step of producing the polyurethane resin foam by stirring a first component containing an isocyanate-terminated prepolymer, a silicone surfactant, and a tertiary amine catalyst with a non-reactive gas so that the non-reactive gas is dispersed as fine cells to prepare a cell dispersion liquid, then mixing the cell dispersion liquid with a second component containing a chain extender, followed by curing the mixture,
wherein the isocyanate-terminated prepolymer is a prepolymer obtained by reacting a prepolymer raw material composition containing a polymerized diisocyanate and an aromatic diisocyanate as isocyanate components, a high molecular weight polyol, and an active hydrogen group-containing low molecular weight compound, and
a content of the tertiary amine catalyst is 0.1 to 3 parts by weight based on 100 parts by weight of the isocyanate-terminated prepolymer.

11. A method for manufacturing a semiconductor device, comprising a step of polishing a surface of a semiconductor wafer by using the polishing pad according to claim 1.
